(19) United States
(12) Patent Application Publication
(10) Pub. No.: US 2007/0080461 A1
(43) Pub. Date: Apr. 12, 2007

(54) Ultra low-k dielectric in damascene structures

(75) Inventors: David Ding-Chung Lu, Hsin-Chu (TW); Hsueh-Chung Chen, Yonghe City (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Comapny, Ltd.

(21) Appl. No.: 11/247,785

(22) Filed: Oct. 11, 2005

(51) Int. Cl. H01L 23/52

(52) U.S. Cl. 257/758

(57) ABSTRACT

A semiconductor structure includes a first dielectric layer having a k value of less than about 2.7, a second dielectric layer over the first dielectric layer, a via in the first dielectric layer, a conductive line in the second dielectric layer, wherein the conductive line extends from a top surface of the second dielectric layer into the second dielectric layer and electrically coupled to the via, a third dielectric layer on the second dielectric layer, and a fourth dielectric layer between the second dielectric layer and the conductive line. The second dielectric layer is preferably a porous material and has an ultra low k value. The k value of the second dielectric layer is lower than the k values of the first, the third and the fourth dielectric layers.

### TECHNICAL FIELD

This invention relates generally to integrated circuit manufacturing processes, particularly to damascene processes, and more particularly to damascene processes using ultra low k dielectrics.

### BACKGROUND

As the semiconductor industry introduces new generations of integrated circuits (IC's) having higher performance and greater functionality, the density of the elements that form the integrated circuits is increased, and the dimensions, sizes and spacing between the individual components or elements are reduced. While in the past such reductions were limited only by the ability to define the structures photo-lithographically, device geometries having even smaller dimensions created new limiting factors. For example, for any two adjacent conductive paths, as the distance between the conductors decreases, the resulting capacitance (a function of the dielectric constant (k) of the insulating material divided by the distance between conductive paths) increases. This increased capacitance results in increased capacitive coupling between the conductors, increased power consumption, and an increase in the resistive-capacitive (RC) time constant. Therefore, continual improvement in semiconductor IC performance and functionality is dependent upon developing materials that form a dielectric film with a lower dielectric constant (k) than that of the most commonly used material, silicon oxide, in order to reduce capacitance. As the dimensions of these devices get smaller and smaller, significant reductions in capacitance into the so-called “ultra low k” regime is required.

New materials with low dielectric constants (known in the art as “low k dielectrics”) are being investigated for their use as insulators in semiconductor chip designs. A low dielectric constant material aids in enabling further reduction in the integrated circuit feature dimensions. In conventional IC processing, SiO₂ is used as a basis for the dielectric material, resulting in a dielectric constant of about 3.9. Moreover, advanced low k dielectric materials have dielectric constants below about 2.7. The substance with the lowest dielectric constant is air (k=1.0). Therefore, porous dielectrics are very promising candidates since they have the potential to provide very low dielectric constants.

However, porous films are mechanically weak by nature. Weak films would fail in the chemical mechanical polish (CMP) process employed to planarize the wafer surface during chip manufacturing. The mechanical properties of a porous film are functions of the porosity of the film. Naturally, higher porosity results in lower dielectric constant but also poorer mechanical properties. Typical ultra low k dielectrics have k values of smaller than about 2.5, pore sizes of greater than about 10 Å and mechanical hardness of less than about 1.5 Gpa.

Due to the mechanical weakness, the usage of ultra low k dielectrics is limited, and thus a method that maximizes the benefit of ultra low k dielectrics while reducing the effects of weak mechanical properties is needed.

### SUMMARY OF THE INVENTION

In accordance with one aspect of the present invention, a semiconductor structure includes a via inter-metal dielectric (IMD) layer having a k value of less than about 2.7, and a trench IMD layer over the via IMD layer. A via is formed in the via IMD layer. The trench IMD layer further includes a trench and a trench liner lining the trench. A metal line electrically coupled to the via fills the trench. The semiconductor structure further includes a dielectric layer over the trench IMD layer. The k value of the trench IMD layer is less than the respective k values of the via IMD layer, the dielectric layer and the trench liner.

In accordance with another aspect of the present invention, instead of a via, a contact plug is formed in the first dielectric layer, and a single damascene process is used to form the conductive line in the trench IMD layer. The conductive line is electrically coupled to the contact plug. The first dielectric layer preferably has a k value of less than about 4.5.

In accordance with yet another aspect of the present invention, a method of forming the semiconductor structure includes forming a first dielectric layer (via IMD layer) and a second dielectric layer (trench IMD layer) over the first dielectric layer, forming a via opening in the first dielectric layer and a trench opening in the second dielectric layer, forming a third dielectric layer (trench liner) on at least the sidewall of the trench opening, filling the via opening and trench opening with conductive materials, preferably copper or copper alloys, and forming a fourth dielectric layer on the second dielectric layer. The k value of the second dielectric is less than about 2.7 and also less than the k values of the first, third and fourth dielectrics. The third and fourth dielectric layers are also sealing layers.

An advantageous feature of the present invention is that the RC delay is reduced since a great portion of the parasitic capacitance is reduced. Another advantageous feature of the present invention is that mechanical strength is improved due to the combination of ultra low k and higher k dielectrics. Additionally, sealing layers avoid the penetration of residue into the ultra low k material during formation processes such as CMP so that the performance of the ultra low k material is not affected. Furthermore, sealing layers prevent conductor degradation from the reaction between the ultra low k material and the conductor after the formation of the semiconductor structure.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 7B are cross-sectional views of intermediate stages in a dual damascene embodiment;

FIGS. 8 and 9 illustrate variations of the preferred embodiment; and

FIGS. 10 through 14 are cross-sectional views of intermediate stages in a single damascene embodiment.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

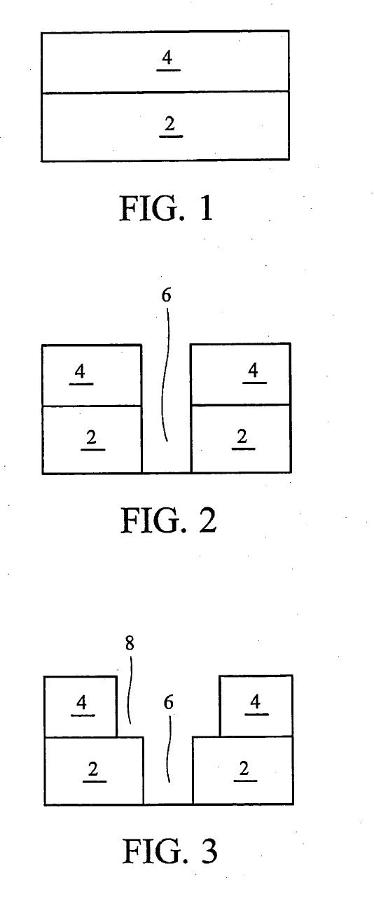

The preferred embodiments of the present invention integrate ultra low k dielectrics and dielectrics with higher k value into a dual damascene process. The cross-sectional views of intermediate stages of the preferred embodiments are illustrated in FIGS. 1 through 7 and FIGS. 10 through 14, wherein like reference numbers are used to designate like elements throughout the various views and illustrative embodiments of the present invention.

FIG. 1 shows the formation of a dielectric layer 2, also referred to as a via inter-metal dielectric (IMD) layer 2. The via IMD 2 preferably has a k value of less than about 2.7 and an average porosity of greater than about ten percent. It can be formed of carbon-doped silicon oxide, fluorine-doped silicon oxide, organic low-k material and porous low-k material, and the like. The via IMD 2 can be formed using methods such as spin-on, chemical vapor deposition (CVD), etc.

An optional interface layer (not shown) is formed over the via IMD layer 2. The interface layer is preferably used as an etch stop layer. It can be deposited on the via IMD layer 2, or formed by treating the via IMD layer 2 using methods such as plasma treatment. The thickness of the interface layer is preferably less than about 200 Å.

A trench IMD 4 is then formed on the via IMD 2. The trench IMD 4 is preferably formed of ultra low k dielectrics with k value of less than about 2.7, and more preferably less than about 2.5. The k value of the trench IMD 4 is also preferably less than the k value of the via IMD 2, more preferably with a difference of greater than about 0.3. The trench IMD 4 comprises porous materials with an average porosity of greater than about 10 percent, and more preferably greater than about 25 percent. The trench IMD 4 can be formed by a spin-on, a chemical vapor deposition (CVD), SOL-GEL, or other known methods.

FIG. 2 illustrates the formation of a via opening 6. A photo resist material (not shown) is formed and patterned over the trench IMD 4. An anisotropic etching, for example, using fluorine containing etching gases, cuts through the trench IMD 4 and via IMD 2, thus forming a via opening 6. In a typical via structure, there may be a conductive material (not shown) underlying the via opening 6, thus process control and end-point detection need to be closely controlled, limiting the likelihood of over-etching through the underlying conductive material.

FIG. 3 illustrates the formation of a trench opening 8. An anisotropic etching cuts through the trench IMD 4, thus forming the trench opening 8. The trench opening 8 will be used to form a conductive line when filled. Since the via IMD 2 and trench IMD 4 have different characteristics, and may even be formed of different materials, the via IMD 2 acts as an etch stop layer, preventing a trench from being formed in the Via IMD 2. However, the interface layer can also be used as an etch stop layer.

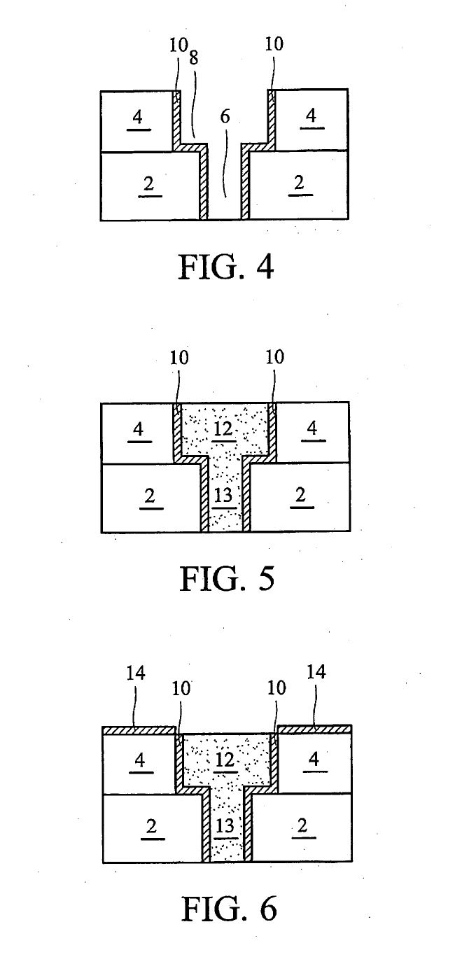

FIG. 4 illustrates a trench liner 10, also referred to as sealing layer 10, formed along the sidewall of the trench opening 8. The trench liner 10 preferably has a k value greater than the k value of the trench IMD 4, and more preferably with a difference of greater than about 0.2. The thickness of the trench liner 10 is preferably less than about 200 Å, and more preferably between about 20 Å and about 100 Å. The preferred methods of formation includes plasma treatment, chemical vapor deposition (CVD), plasma enhanced CVD (PECVD), atomic layer (ALCVD) and other known methods. In the preferred embodiment, the trench liner 10 is formed by treating the sidewall of the IMD 4 using plasma and converting a top layer of the IMD 4 into the trench liner 10. In other embodiments, the trench liner 10 is thermal oxide. In yet other embodiments, the trench liner 10 contains Si₃N₄, SiO₂, SiON, SiOC, SiOCN, and combinations thereof. Trench liner 10 covers at least the sidewall of the trench IMD 4 and preferably covers the exposed surface of the via IMD 2. The bottom of the via opening 6 is preferably not covered by the trench liner 10.

FIG. 5 illustrates the formation of a conductive line 12 and a via 13 in trench opening 8 and via opening 6, respectively. The via opening 6 and trench opening 8 are filled with conductive materials, preferably copper or copper alloys. A chemical mechanical planarization (CMP), also sometimes referred to as chemical mechanical polish, is performed to planarize the surface of the trench IMD 4 and remove excessive material. A barrier layer (not shown), which prevents copper from diffusing into the trench IMD 4 and via IMD 2, may be formed before the conductive line 12 and via 13 are formed. The barrier layer is preferably formed of a material comprising titanium, titanium nitride, tantalum, tantalum nitride, and combinations thereof. It may also include multi-layers.

A dielectric layer 14, also referred to as sealing layer 14, is formed covering the trench IMD 4, as illustrated in FIG. 6. The dielectric layer 14 preferably has a k value of greater than the k value of the trench IMD 4, and more preferably with a difference of greater than about 0.2. The dielectric layer 14 has a preferred thickness of greater than about 300 Å. In the preferred embodiment, the dielectric layer 14 is formed by treating the IMD 4. For example, plasma treatment to the trench IMD 4 increases the density of a top layer and converts it into the dielectric layer 14. In other embodiments, the dielectric layer 14 is deposited using commonly used methods such as CVD, PECVD, ALCVD, etc.

The sealing layers 10 and 14 have the additional function of avoiding the penetration of residue into the ultra low k material 4 during CMP or other processes so that performance of the ultra low k material is not affected. Additionally, the ultra low k material 4 may react with conductors if they are in direct contact. The sealing layers 10 and 14 prevent such reaction even after the preferred embodiments are formed.

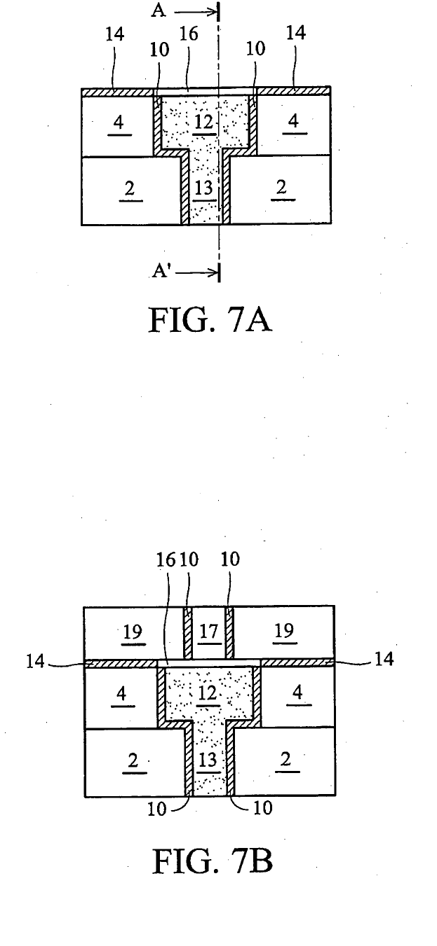

FIG. 7A illustrates a conductive cap 16 formed on the conductive line 12. The conductive cap 16 preferably comprises conductive materials such as cobalt, nickel, tungsten, molybdenum, tantalum, etc., and has a thickness of 25 nm, and more preferably between about 10 nm and 40 nm. The conductive cap 16 preferably has a better characteristic match with the overlying dielectric layer than the conductive line 12, and thus acts as a buffer layer between the conductive line 12 and the overlying dielectric layer. This helps reduce electro-migration and stress-migration and thus improves device reliability, and reduces chemical penetration into layer 4 through gaps between sealing layers 10 and 14. In the preferred embodiment, the conductive cap layer 16 can be formed using chemical vapor reaction (CVR), electroless plating, sputtering, CVD, or other commonly known methods.

The conductive line 12 may be further coupled to other conductive lines in higher-level metal layers through via (or vias) 17 above the conductive line 12, as shown in FIG. 7B. As will be described in subsequent paragraphs, the via(s) 17 is preferably formed in a dielectric layer 19 having a k value of greater than the k value of the IMD 4.

In the preferred embodiments of the present invention, the ultra low k dielectric 4 is surrounded by dielectric materials 2, 10, and 14, which have higher k values, and possibly the conductive layer 16, hence having greater mechanical strength and improved reliability. Comparing the conductive line 12 and via 13, the conductive line 12 has significantly greater cross sectional (along line A-A′) area than the via 13. Therefore, the parasitic capacitance between the conductive line 12 and other conductive lines in the same metal layer is significantly greater than the parasitic capacitance between the via 13 and other vias. By using ultra low k dielectrics for the trench IMD 4, the overall parasitic capacitance is significantly reduced. Since the parasitic capacitance between vias is relatively insignificant, the via IMD 2 is preferably formed of dielectrics having higher k values and greater mechanical strength. This combination improves the electrical performance of the devices while minimizing the drawbacks.

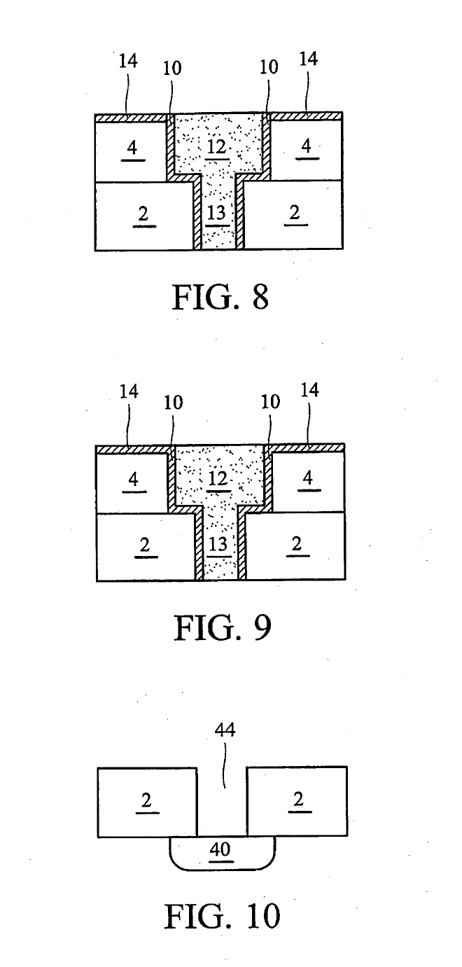

One skilled in the art will realize that trench liner 10 and dielectric layer 14 can be formed in different orders and with the same or different materials. For example, in FIG. 8, the dielectric layer 14 is formed before the formation of the trench liner 10. In FIG. 9, the trench liner 10 and dielectric layer 14 are formed simultaneously. After the structure shown in FIG. 3 is formed, each of the trench liner 10 and dielectric layer 14 can be either deposited, or formed by treating the trench IMD 4, preferably using plasma treatment.

FIGS. 10 through 13 illustrate a single damascene embodiment of the present invention. FIG. 10 includes a dielectric layer 2 having a k value of less than about 4.5. An opening 44 is formed through the dielectric layer 2, exposing a region 40. In the preferred embodiment, the dielectric layer 2 is an inter-layer dielectric (ILD), and the region 40 may be a portion of a semiconductor device, such as a silicide on a gate electrode, a source/drain region, a silicide on source/drain region, etc., or a conductive component electrically coupled to a semiconductor device.

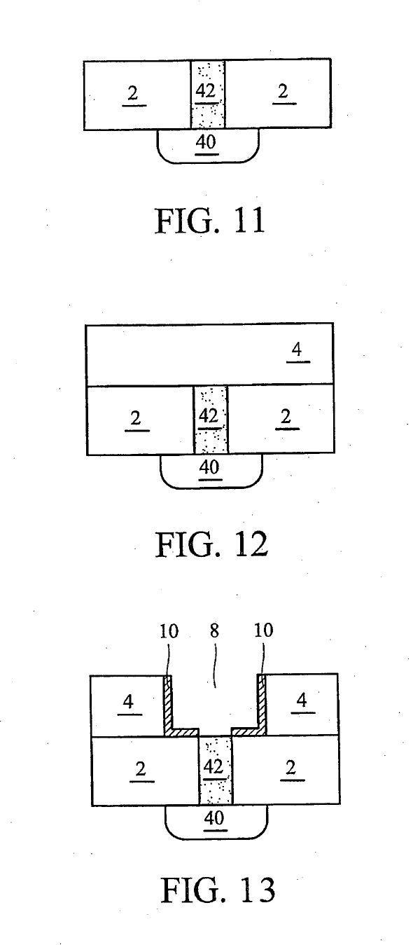

FIG. 11 illustrates a contact plug 42, which is vertical in orientation, formed in the opening 44. The contact plug 42 may be formed of tungsten, aluminum, copper, refractive alloys or other well-known alternatives, and may have composite structures, including, e.g. barrier and adhesion layers, such as titanium/titanium nitride or tantalum nitride, and other layers as well.

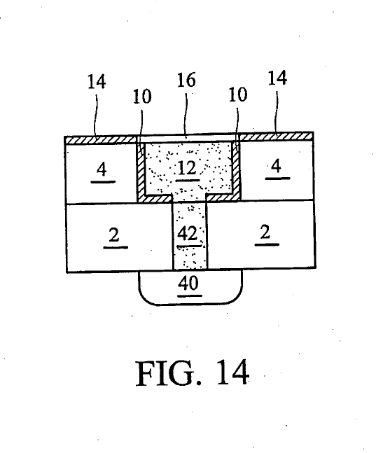

A dielectric layer 4 is then formed over the dielectric layer 2 and the contact plug 42, as illustrated in FIG. 12. Formed of ultra low k dielectrics, the dielectric 4 preferably has a k value of less than about 2.7, more preferably less than about 2.5. Also, the k value of the dielectric 4 is preferably lower than the k value of the dielectric 2, and more preferably with a difference of greater than about 0.5. FIG. 13 illustrates an opening 8 formed in the dielectric layer 4, exposing the contact plug 42. A dielectric liner 10 is then formed covering at least the sidewall of the dielectric layer 4, and the resulting structure is shown in FIG. 13. As shown in FIG. 14, a dielectric layer 14, a conductive line 12, and a conductive cap 16 are formed. The dielectric liner 10 and the dielectric 14 preferably have greater k value than the dielectric layer 4. The details of the formation are similar to the previously discussed embodiment (please refer to FIGS. 5, 6, and 7) and are not repeated.

Due to greater cross sectional area, greater parasitic capacitance exists between the conductive line 12 and other conductive lines. By using ultra low k dielectric materials for the dielectric 4, the overall reduction of the parasitic capacitance is significant. Also, since the parasitic capacitance between the metal plug 42 and other metal plugs is relatively small, the dielectric material 2 preferably has a greater k value, hence having greater mechanical strength, than the dielectric 4.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a first dielectric layer having a first dielectric constant (k value) of less than about 2.7;
a via in the first dielectric layer;
a second dielectric layer over the first dielectric layer, the second dielectric layer having a second k value of less than the first k value;
a conductive line in the second dielectric layer, the conductive line extending from a top surface of the second dielectric layer into the second dielectric layer and electrically coupled to the via;
a third dielectric layer on the second dielectric layer, the third dielectric layer having a third k value of greater than the second k value; and
a fourth dielectric layer having a fourth k value of greater than the second k value between the second dielectric layer and the conductive line.

2. The semiconductor structure of claim 1 further comprising a conductive cap over the conductive line.

3. The semiconductor structure of claim 1 wherein the second dielectric layer has an average porosity of greater than about twenty five percent.

4. The semiconductor structure of claim 1 wherein the first dielectric layer has an average porosity of greater than about ten percent.

5. The semiconductor structure of claim 1 wherein the second k value is less than each of the first k value, the third k value and the fourth k value by at least about 0.2.

6. The semiconductor structure of claim 1 wherein the third dielectric layer has a thickness of greater than about 300 Å.

7. The semiconductor structure of claim 1 wherein the fourth dielectric layer extends between the first dielectric layer and the via.

8. The semiconductor structure of claim 7 wherein the fourth dielectric layer has a thickness of less than about 200 Å.

9. The semiconductor structure of claim 1 wherein the third dielectric layer and the fourth dielectric layer are formed of the same materials.

10. The semiconductor structure of claim 1 further comprising an interface dielectric layer having a thickness of less than about 200 Å between the first and the second dielectric layers.

11. The semiconductor structure of claim 1 further comprising:
an additional dielectric layer having a k value of greater than the second k value over the third dielectric layer and the conductive line; and
an additional via in the additional dielectric layer, the additional via extending from a top surface of the additional dielectric layer into the additional dielectric layer and electrically coupled to the conductive line.

12. An integrated circuit comprising:
a via inter-metal dielectric (IMD) layer having a first k value of less than about 2.7;
a via in the via IMD layer;
a trench IMD layer over the via IMD layer, the trench IMD layer having a second k value of less than the first k value;
a trench in the trench IMD layer;
a trench liner having a third k value of greater than the second k value lining the trench;
a metal line filling the trench, the metal line being electrically coupled to the via; and
a dielectric layer on the trench IMD layer, the dielectric layer having a fourth k value of greater than the second k value.

13. The integrated circuit of claim 12 wherein the trench IMD layer has an average porosity of greater than about twenty five percent.

14. The integrated circuit of claim 12 further comprising a conductive cap over the metal line.

15. The integrated circuit of claim 12 wherein the second k value is less than the respective first, third and fourth k values by at least about 0.2.

16. The integrated circuit of claim 12 wherein the trench liner has a thickness of less than about 200 Å.

17. A semiconductor structure comprising:
a first dielectric layer having a first k value of less than about 4.5;
a second dielectric layer over the first dielectric layer, the second dielectric layer having a second k value of less than the first k value;
a vertical conductive line in the first dielectric layer;
a horizontal conductive line in the second dielectric layer, the horizontal conductive line extending from a top surface of the second dielectric layer into the second dielectric layer and electrically coupled to the vertical conductive line;
a third dielectric layer over the second dielectric layer, the third dielectric layer having a third k value of greater than the second k value; and
a fourth dielectric layer having a fourth k value of greater than the second k value between the second dielectric layer and the horizontal conductive line.

18. The semiconductor structure of claim 17 wherein the second dielectric layer has a porosity of greater than about twenty five percent.

19. The semiconductor structure of claim 17 wherein the third dielectric layer has a thickness of greater than about 300 Å.

20. The semiconductor structure of claim 17 wherein the vertical conductive line is a contact plug.

21. The semiconductor structure of claim 17 wherein the vertical conductive line is a via, and the first dielectric constant of the first dielectric layer is less than about 2.7.

22. The semiconductor structure of claim 17 wherein the fourth dielectric layer has a thickness of less than about 200 Å.
